(19) United States
(12) Patent Application Publication
(10) Pub. No.: US 2014/0306202 A1
(43) Pub. Date: Oct. 16, 2014

(54) Organic Field Effect Transistor and Method for Production

(71) Applicants: Novaled GmbH, Dresden (DE); Technische Universitaet Dresden, Dresden (DE)

(72) Inventors: Hans Kleemann, Dresden (DE); Bjoern Luessem, Dresden (DE); Karl Leo, Dresden (DE)

(73) Assignees: Novaled GmbH, Dresden (DE); Technische Universitaet Dresden, Dresden (DE)

(21) Appl. No.: 14/248,437

(22) Filed: Apr. 9, 2014

(30) Foreign Application Priority Data
Apr. 10, 2013 (EP) 13163215.0

(51) Int. Cl. H01L 51/05; H01L 51/00

(52) U.S. Cl. CPC H01L 51/0512; H01L 51/0001
USPC 257/40; 438/99

(57) ABSTRACT

The present disclosure relates to an organic field effect transistor, comprising a first electrode and a second electrode, the electrodes providing a source electrode and a drain electrode, a gate electrode, an electronically active region at least in part made of an organic material and providing a charge a carrier channel, and a gate electrode separation, comprising a doped organic semiconducting layer directly provided on the gate electrode, wherein the doped organic semiconducting layer comprises an organic matrix material and an organic dopant. Furthermore, a method for producing an organic field effect transistor is provided.

### CROSS-REFERENCE TO RELATED APPLICATIONS

This application claims foreign priority under 35 U.S.C. §119 to European Patent Application No. 13 163 215.0, filed Apr. 10, 2013. The subject matter of European Patent Application No. 13 163 215.0 is incorporated herein by reference.

### FIELD OF THE INVENTION

The invention refers an organic filed effect transistor and a method for production.

### BACKGROUND

Ever since the invention of organic field effect transistors (OFETs) in the 1980s their performance could be continuously improved. Nowadays, OFETs are used for driving e-ink displays, printed RFID tags, and flexible electronics. The advantages of OFETs compared to silicon technology are the possibility to realize thin and flexible circuits at low process temperatures on large areas. Despite this progress, the widespread application of OFETs is still limited due to their low performance and stability. However, there is a large potential for improvement by the development of advanced OFET structures.

There are different types of transistor structures known, such as inversion FET (IFET), depletion FET (DFET) or junction FET (JFET). All those structures may be realized as an organic FET. In general, an organic field effect transistor comprises a gate electrode, a source electrode and a drain electrode. In general, the OFET comprises an organic semiconductor and a gate insulator which separates the gate electrode from the organic semiconductor and which is made of an inorganic material.

The organic doping technology has been shown to be a useful technology for highly efficient opto-electronic devices such as organic light emitting devices or organic solar cells. The use of doped organic layers in organic transistors has also been proposed. For example, doping can be used to reduce the contact resistance at the source and drain contacts. A thin p- or n-doped layer between the metallic contact and the organic semiconductor forms an ohmic contact which increases the tunnel currents and enhances the injection.

It has been reported that the threshold voltage can be shifted by the doping concentration. Meijer et al. Journal of Applied Physics, vol. 93, no. 8, p. 4831, 2003, studied the effect of doping by oxygen exposure on polymer transistors. Although a shift of the switch-on voltage (the flatband voltage) was observed, the effect was not related to doping by the authors. Similarly, other authors found a similar shift of threshold voltage with applying a dopant, but often this effect is rather related to the influence of contact doping than to channel doping.

Inversion FETs are normally OFF and an inversion channel has to be formed by an applied gate voltage in order to switch the transistor ON. Inversion FETs are used in silicon CMOS circuits and are the most basic building block of all integrated circuits. It is known that the inversion regime cannot be reached in organic MIS (metal insulator semiconductor) capacitors. However, it has been predicted by simulations that an inversion channel can be formed in FET structures, if minority carriers are injected at the source and drain electrodes. Huang et al. Journal of Applied Physics, vol. 100, no. 11, p. 114512, 2006, could show that a normally n-conducting intrinsic material can be made p-conductive by charging the gate insulator prior to deposition of the organic layer by a corona discharge.

An organic metal semiconductor field effect transistor is proposed in Braga et al. Adv. Material, 2010, 22, 424-428.

Document US 2010/0096625 A1 discloses an organic field effect transistor comprising a substrate on which a source and a drain electrode are arranged. A semiconducting layer is deposited on top of the electrodes and in electrical contact with the electrodes. The semiconducting layer is formed with a lower sublayer and an upper sublayer. On top of the upper sublayer a dielectric layer and a gate electrode are provided. The semiconductor materials of the semiconducting layer may contain inorganic particles such as nanotubes or conductive silicon filaments. The lower and upper sublayer can be n-type or p-type and can have doping of the same kind.

In document U.S. Pat. No. 5,629,530 a field effect transistor with a source region, a drain region and a interposed n-type channel region is disclosed. The channel region is provided with a gate electrode that is separated from the channel region by an insulating layer.

An organic thin film transistor is described in document US 2006/0033098 A1. The transistor comprises a substrate, a gate electrode, a gate dielectric layer which covers the entire gate electrode, a source electrode, a drain electrode, an active channel layer and a source interfacial layer. A potential barrier between the source electrode and the active channel layer is reduced by adding an agent into the active channel layer.

The document EP 2 194 582 A1 describes an organic thin film transistor with a substrate, a gate electrode, a source electrode, a drain electrode, an insulator layer, an organic semiconducting layer and a channel control layer that is arranged between the organic semiconducting layer and the insulator layer. The channel control layer includes an amorphous organic compound having an ionization potential of less than 5.8 eV.

In document US 2003/0092232 A1 a further field effect transistor is disclosed.

### BRIEF SUMMARY

It is an object of the invention to provide an organic field effect transistor with optimized working parameters and a method for producing the transistor.

According to one aspect, an organic field effect transistor is provided. The transistor comprises a first electrode and a second electrode, the electrodes providing a source electrode and a drain electrode. There is a gate electrode. Also, an electronically active region is provided, the electronically active region being made at least in part of an organic material and providing a charge carrier channel. There is a gate electrode separation covering and separating the gate electrode. The gate electrode separation comprises an electrically doped organic semiconducting layer directly provided on the gate electrode, wherein the doped organic semiconducting layer comprises an organic matrix material and an organic electrical dopant.

According to another aspect, a method for producing an organic field effect transistor is provided, comprising steps of providing a substrate, and depositing a layered structure on the substrate. The layered structure is produced with a first electrode and a second electrode, the electrodes providing a source electrode and a drain electrode, a gate electrode, an electronically active region at least in part made of an organic material and providing a charge carrier channel, and a gate electrode separation, comprising a doped organic semiconducting layer directly provided on the gate electrode, wherein the doped organic semiconducting layer comprises an organic matrix material and an organic dopant.

The transistor may implement a junction OFET.

In the transistor, the gate electrode separation may be provided as a multilayer separator.

The gate electrode separation as whole may be made of organic material(s). It may be provided free of an inorganic insulator.

The transistor may comprise an additional doped organic semiconducting layer, the additional or further doped organic semiconducting layer comprising an organic matrix material and an organic dopant and being provided between the doped organic semiconducting layer and the first and second electrode. The additional doped organic semiconducting layer may be provided adjacent to the first and second electrode. It may be in direct contact with at least one of the first electrode and the second electrode.

The doped organic semiconducting layer may provided with a first type of electrical doping, and the additional doped organic semiconducting layer may be provided with a second type of electrical doping which is different from the first type of electrical doping. The first type of electrical doping may be an n-type doping or a p-type doping. The second type of electrical doping may be a p-type doping or an n-type doping.

In addition to the doped organic semiconducting layer and the additional doped organic semiconducting layer, at least one other doped organic semiconducting layer may be provided. The at least one other electrically doped organic semiconducting layer may be implemented as contact improving layer providing improved electrical (injection) contact between the material of the first and/or the material of the second electrode and a layer adjacent to the contact improving layer within the electronically active region.

The transistor may further comprise an intrinsic semiconducting layer. The term “intrinsic” as used here refer to an un-doped semiconducting layer which is not electrically doped.

The intrinsic semiconducting layer may be provided between the doped organic semiconducting layer and the additional doped organic semiconducting layer.

The intrinsic semiconducting layer may be provided in direct contact with at least one of the doped organic semiconducting layer and the additional doped organic semiconducting layer. The intrinsic semiconducting layer may completely separate the doped organic semiconducting layer and the additional doped organic semiconducting layer. A pin-layer structure, e.g. a pin-diode, may be provided by the doped organic semiconducting layer, the intrinsic layer and the additional doped organic semiconducting layer. The term “pin” refers to a layer structure made of a p-doped semiconducting layer, an intrinsic layer and an n-doped semiconducting layer.

The intrinsic semiconducting layer may be an organic intrinsic semiconducting layer made of an organic material. An organic pin-layer structure may be provided.

The intrinsic semiconducting layer may be provided with a layer thickness of about 10 nm to about 50 nm, preferably of about 20 nm to about 40 nm.

At least one of the doped organic semiconducting layer and the additional doped organic semiconducting layer may be provided with a layer thickness of about 2 nm to about 50 nm preferably of about 4 nm to about 20 nm.

The transistor may comprise an electrode pattern, the electrode pattern providing at least one of the first and second electrode and the gate electrode with an electrode structure, and providing a non-overlapping electrode pattern for the gate electrode on one hand and the first and second electrode on the other hand. Looking at the device plane the gate electrode does not overlap with both the first and the second electrode. In the process of device production, the electrode pattern may be produced by using a shadow mask technology and/or a lithography technology.

The materials of the gate electrode as well as the first and second electrode may be deposited by vacuum thermal evaporation (VTE). Alternatively, the electrode materials may be ink-jet printed while applying a conductive paste. Preferably, the layers of the OFET, namely at least one of the gate electrode, the first electrode, the second electrode, the intrinsic semiconducting layer, the doped organic semiconducting layer, and the additional doped organic semiconducting layer may be structured by using shadow mask technology. Alternatively or supplementary, the layers of the OFET can be structured by optical lithography. The organic material for the intrinsic semiconducting layer may be deposited by thermal evaporation under ultra high vacuum (UHV) conditions. The organic material of the intrinsic semiconducting layer may be deposited prior to the deposition of the other electrode material of the first and second electrode using the same shadow mask. Herewith, an efficient injection of charge carriers at the first and second electrode is ensured. Alternatively, the organic field effect transistor can be produced by solution based methods such as blade coating, spin coating and spray coating. Preferably, the transistor is produced by roll-to-roll coating.

At least one electrode selected from the following group may be made of a metallic material: the first electrode, the second electrode, and the gate electrode. The gate electrode can be formed by metals such as Al, Au, Ag, Ti, Pt, for example. If the first and/or second electrode shall inject electrons it may be formed by metals with a low work function, e.g. Ti or Al. If the first and/or second electrode shall inject holes it/they may be formed by metals with a large work function, e.g. Au, Ag, ITO.

The intrinsic semiconducting layer and the doped organic semiconducting layer(s) may comprise the same organic matrix material. Alternatively, the intrinsic organic semiconducting layer and the doped organic semiconducting layer(s) may comprise different matrix materials.

The organic dopant is a dopant made of an organic material. It is preferably an electrical dopant. Providing an electrical organic dopant in a matrix material leads to a charge transfer between the dopant and the matrix material. Electrical dopants are classified in p-dopants (oxidation reaction) and n-dopants (reduction reaction). Electrical doping is well known in the field, exemplary literature references are Gao et al, Appl. Phys. Lett. V. 79, p. 4040 (2001), Blochwitz et al, Appl. Phys. Lett. V. 73, p. 729 (1998), D'Andrade et al. App. Phys. Let. V. 83, p. 3858 (2003), Walzer et al. Chem. Rev. V. 107, p. 1233 (2007), US 2005/040390 A1, US 2009/179189 A. Preferred p-doping compounds are organic molecules containing cyano groups.

The organic dopant may be spatially distributed in the matrix material of the doped organic semiconducting layer instead of being accumulated at an interface of the layer. The distribution of the dopant may be homogeneous along the dimensions of the layer. The matrix material (host)/dopant system may be chosen with respect to the energy levels of a matrix and a dopant material. For a preferable combination of host and dopant the activation energy required for doping is less than the 50 meV. Such activation energy can be determined by temperature dependent capacitance-voltage measurements. Low activation energy is preferable since this guarantees a temperature independent threshold voltage of the inversion FET.

Exemplary p-dopants are:
tetrafluoro-tetracyanoquinonedimethane (F4TCNQ),
2,2′-(perfluoronaphthalene-2,6-diylidene)dimalononitrile,
2,2′,2″-(cyclopropane-1,2,3-triylidene)tris(2-(p-cyanotetrafluorophenyl)acetonitrile), and
2,2′,2″-(cyclopropane-1,2,3-triylidene)tris(2-(2,6-dichlor-3,5-difluor-4-(trifluormethyl)phenyl)acetonitrile),
2,2′,2″-(cyclopropane-1,2,3-triylidene)tris(2-(perfluorphenyl)acetonitrile),
2,2′,2″-(cyclopropane-1,2,3-triylidene)tris(2-(2,6-dichloro-3,5-difluoro-4-(trifluormethyl)phenyl)-acetonitrile), and
3,6-difluoro-2,5,7,7,8,8-hexacyanoquinodimethane (F2CN2TCNQ or F2-HCNQ).

Exemplary n-dopants are:
acridine orange base (AOB),
tetrakis(1,3,4,6,7,8-hexahydro-2H-pyrimido[1,2-a]pyrimidinato)ditungsten(II) (W2(hpp)4),
3,6-bis-(dimethyl amino)-acridine, and
bis(ethylene-dithio)tetrathiafulvalene (BEDT-TTF).

Preferable host-dopant combinations are (Table 1):

| matrix material (host) | dopant |
|---|---|
| N4,N4,N4′,N4′-tetrakis(4-methoxy- | 2,2′-(perfluoronaphthalene- |
| phenyl)biphenyl-4,4′-diamine (Meo-TPD) | 2,6-diylidene)dimalononitrile |
| | (F6-TCNNQ) |
| Meo-TPD | F4-TCNQ |
| Meo-TPD | C60F36 |
| Pentacene | F6-TCNNQ |
| Tris(1-phenylisoquinoline)iridium(III) | F6-TCNNQ |
| (Ir(piq)3) | |
| Pentacene | F4-TCNQ |
| C60 | W2(hpp)4 |
| C60 | Cr2(hpp)4 |
| C60 | AOB |
| Pentacene | W2(hpp)4 |
| Copper(II)-1,2,3,4,8,9,10,11,15,16,17,18, | W2(hpp)4 |
| 22,23,24,25-hexadecafluor-29H,31H- | |
| phthalocyanin (F16CuPc) | |

In the electrically doped regions, the dopant may be provided with a concentration of up to 4 wt %, preferably between 0.5 wt % and 4 wt %. More preferably, the dopant concentration may be between 0.5 wt % and 2 wt %.

To reduce parasitic leakage currents in the transistor, the doped organic semiconducting layer(s) may be as thin as possible. On the other hand, it has to be thick enough to form a percolated layer, more preferably a closed layer, and to control the Fermi Level in the doped organic semiconducting layer.

The intrinsic semiconducting layer is free of an electrical dopant material. The intrinsic semiconducting layer may be made from a single organic material. This material can also be called a matrix material even if no electrical dopant is present.

The intrinsic semiconducting layer and/or the doped organic semiconducting layer(s) may comprise a matrix material having one of the following structures: crystalline, poly-crystalline, amorphous and a combination thereof.

### BRIEF DESCRIPTION OF THE DRAWINGS

Following further embodiments are described in further detail, by way of example, with reference to figures. In the figures show:

FIGS. 1A-1D are schematic representations of an organic field effect transistor (OFET) of the junction type, FIG. 1A is a top gate bottom contact device, FIG. 1B depicts a device in which there is no direct overlap between the source electrode or drain electrode or gate electrode, FIG. 1C is a depiction of a top contact and bottom gate device, and FIG. 1D depicts a device in which there is no direct overlap between the source electrode or drain electrode or gate electrode,

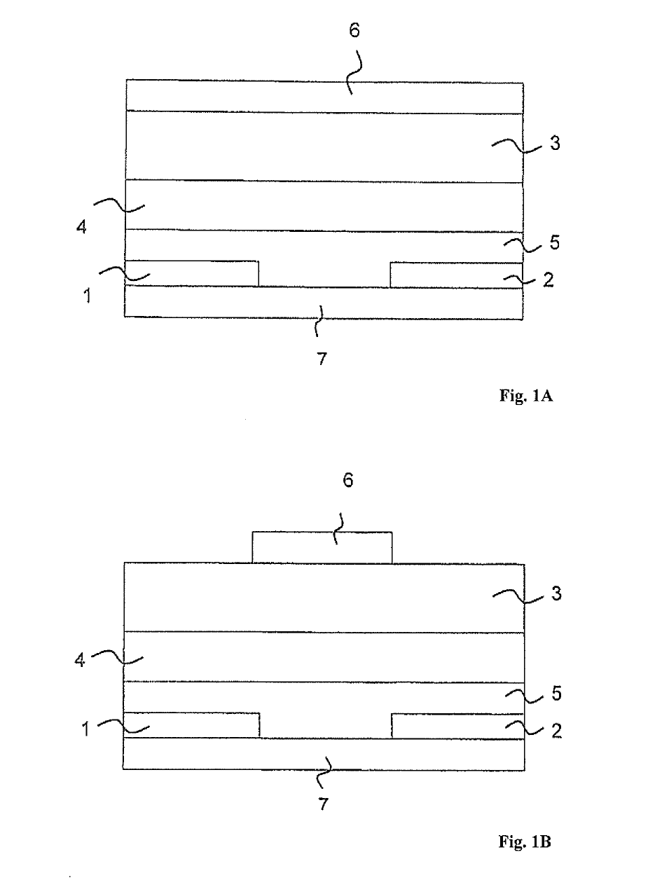

FIG. 2 a graphical representation of the source current in dependence on the gate-source voltage,

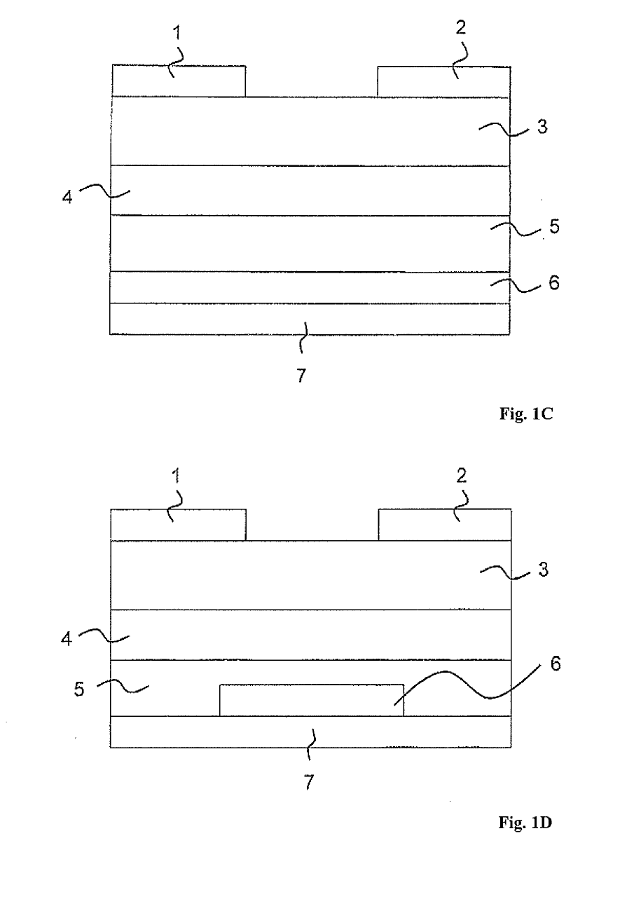

FIG. 3 a graphical representation of the source current in dependence on the source-drain voltage,

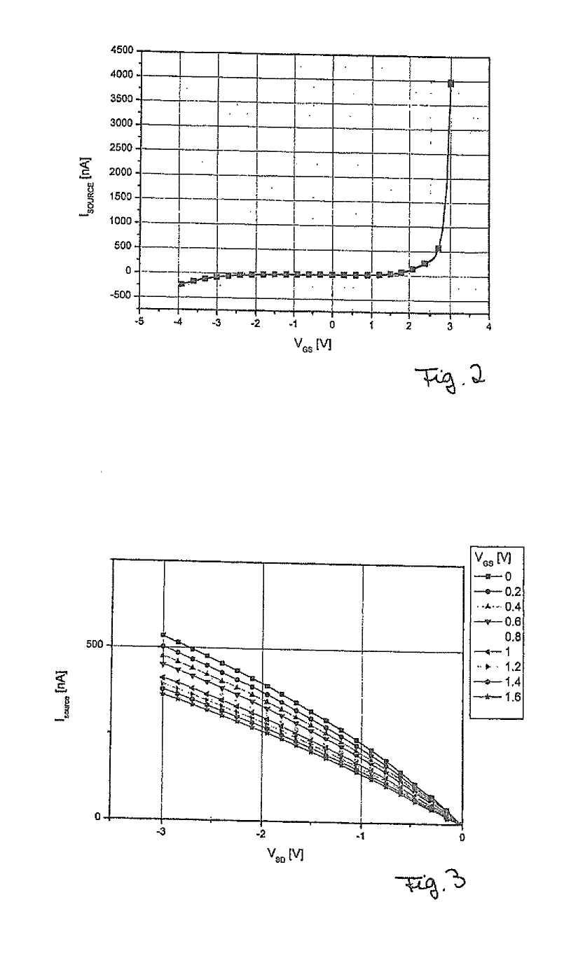

FIG. 4 a graphical representation of the source current in dependence on the gate voltage,

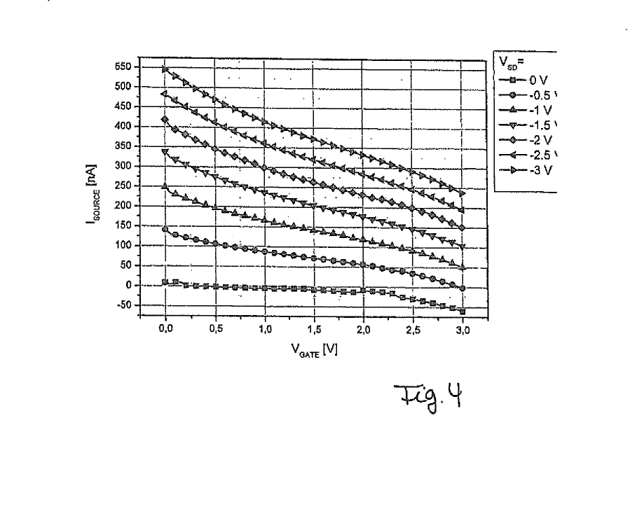

FIG. 5 a graphical representation of the current in dependence on the voltage (device characteristic) for pin diodes having an intrinsic layer of different thickness,

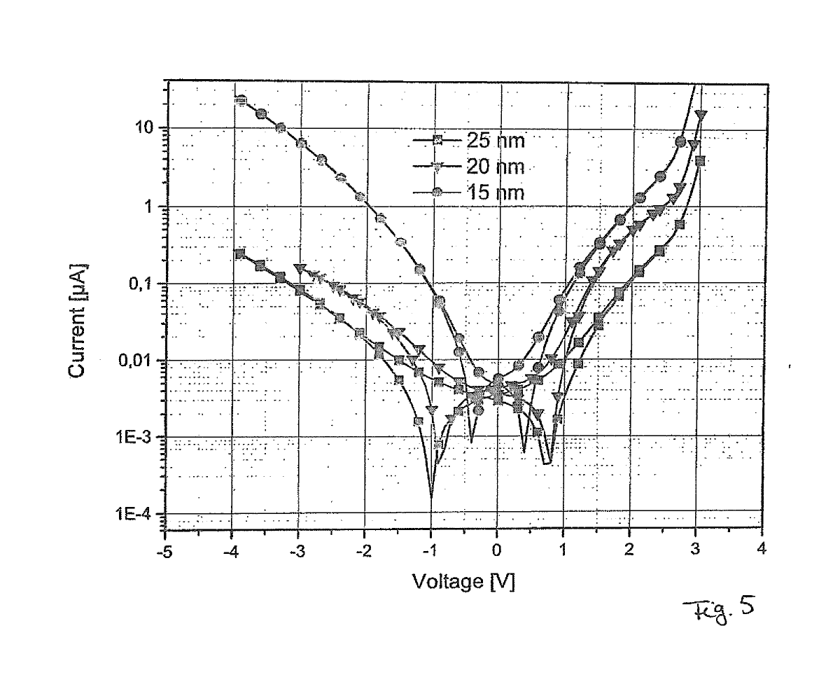

FIG. 6 a graphical representation of the source current in dependence on the source-drain voltage for devices having an intrinsic layer of different thickness, and

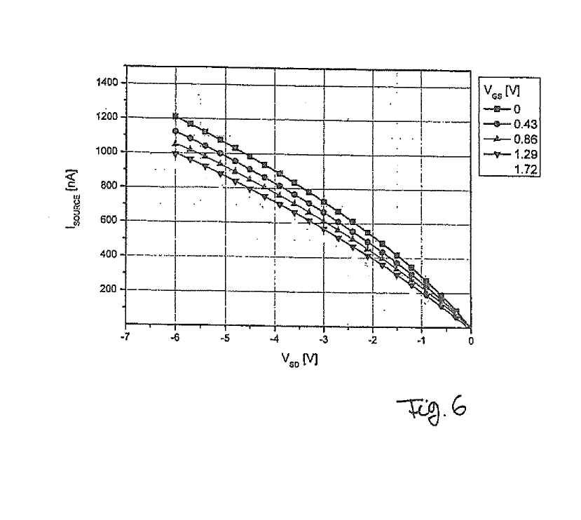

FIG. 7 a graphical representation of the source current in dependence on the source-drain voltage for varying intrinsic layer thickness and p-doped layer thickness.

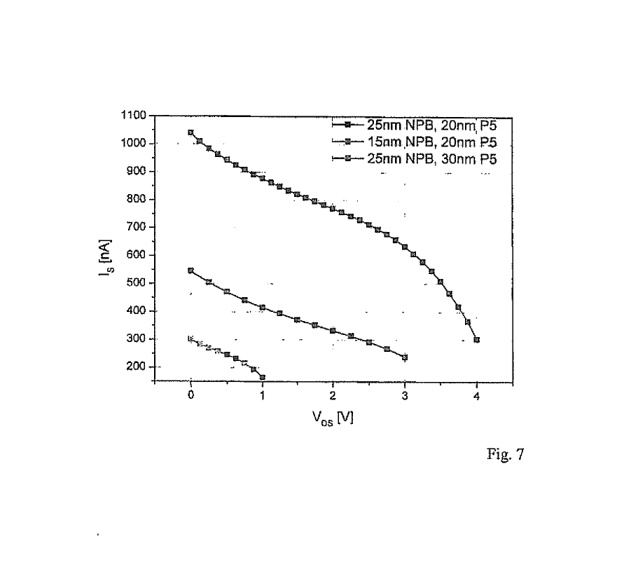

1. An organic field effect transistor, comprising:
a first electrode and a second electrode, wherein the first and second electrodes are a source electrode and a drain electrode,
a gate electrode,
an electronically active region comprising a charge carrier channel, wherein the electronically active region comprises an organic material, and
a gate electrode separation comprising a first doped organic semiconducting layer arranged directly on the gate electrode, wherein the first doped organic semiconducting layer comprises an organic matrix material and an organic dopant.

2. A transistor according to claim 1, wherein the gate electrode separation is a multilayer insulation.

3. A transistor according to claim 1, wherein the gate electrode separation is made of organic material.

4. A transistor according to claim 1, further comprising a second doped organic semiconducting layer, wherein the second doped organic semiconducting layer comprises an organic matrix material and an organic dopant, and is arranged adjacent to the first and second electrode.

5. A transistor according to claim 4, wherein the first doped organic semiconducting layer is doped according to a first type of electrical doping, and the second doped organic semiconducting layer is doped according to a second type of electrical doping which is different from the first type of electrical doping.

6. A transistor according to claim 1, further comprising an intrinsic semiconducting layer.

7. A transistor according to claim 6, wherein the intrinsic semiconducting layer is arranged between the first doped organic semiconducting layer and the second doped organic semiconducting layer.

8. A transistor according to claim 6, wherein the intrinsic semiconducting layer is in direct contact with at least one of the first doped organic semiconducting layer and the second doped organic semiconducting layer.

9. A transistor according to claim 6, wherein the intrinsic semiconducting layer is an organic intrinsic semiconducting layer comprising an organic material.

10. A transistor according to claim 6, wherein the intrinsic layer has a layer thickness of from about 10 nm to about 500 nm.

11. A transistor according to claim 1, wherein at least one of the first doped organic semiconducting layer and the second doped organic semiconducting layer has a layer thickness of from about 2 nm to about 50 nm.

12. A transistor according to claim 1, further comprising an electrode pattern.

13. A method for producing an organic field effect transistor, comprising steps of:
providing a substrate, and
providing a layered structure on the substrate, the layered structure comprising
a first electrode and a second electrode, wherein the first and second electrodes are a source electrode and a drain electrode,
a gate electrode,
an electronically active region comprising a charge carrier channel, wherein the electronically active region comprises an organic material, and
a gate electrode separation comprising a first doped organic semiconducting layer arranged directly on the gate electrode, wherein the first doped organic semiconducting layer comprises an organic matrix material and an organic dopant.

14. A transistor according to claim 12, wherein the electrode pattern provides an electrode structure for at least one of (1) the first and second electrode and (2) the gate electrode, wherein when the electrode structure is provided for both the first and second electrode and the gate electrode, the electrode structure of the first and second electrode, and the gate electrode are non-overlapping electrode patterns.
